(19) United States
(12) Patent Application Publication
(10) Pub. No.: US 2003/0139069 A1
(43) Pub. Date: Jul. 24, 2003

(54) Planarization of silicon carbide hardmask material

(76) Inventors: Kelly H. Block, Boothwyn, PA (US); Vikas Sachan, Richardson, TX (US)

Correspondence Address: Rodel Holdings, Inc., Suite 1300, 1105 North Market Street, Wilmington, DE, 19899, US

(21) Appl. No.: 10/305,572

(22) Filed: Nov. 27, 2002

Related U.S. Application Data
(60) Provisional application No. 60/338,107, filed on Dec. 6, 2001.

(51) Int. Cl. H01L 21/302; H01L 21/461

(52) U.S. Cl. 438/962; 438/692

(57) ABSTRACT

Disclosed is a chemical mechanical planarizing method useful for removing silicon carbide hardmask capping materials in the presence of Low-k dielectrics contained on semiconductor wafers. The method uses zirconia-containing slurries at acidic pH levels with the abrasive having a positive zeta potential to facilitate silicon carbide removal.

This application claims the benefit of U.S. Provisional Application No. 60/338,107, filed Dec. 6, 2001.

### BACKGROUND OF THE INVENTION

The integration of copper with low dielectric constant (Low-k) materials is critical to the development of the next-generation for ultra-large-scale-integrated circuit (ULSI) technologies. The Low-k dielectric materials, will improve speed, reliability and circuit density in ULSI devices. In some integration schemes for these devices, coupling copper with Low-k inter-layer dielectric (ILD) or inter-metal dielectric (IMD) materials (i.e. dual-damascene applications) will reduce device resistance and capacitance; and therefore they will also improve the RC time constant in these interconnect devices.

At this time, there are many different proposed chemical types of Low-k materials, each associated with a specific Low-k value. The two main classes of Low-k materials are chemical vapor deposition (CVD) and spin-on dielectric (SOD) films. The SOD classifications further include inorganic and organic spin-on materials. In addition to the various types of Low-k dielectric materials, various integration schemes will protect Low-k dielectric materials with different hardmask capping layers. Some integration schemes may include dual-top hardmasks such as, SiO₂/SiC, over the Low-k dielectric; and other integration architectures may incorporate single-top hardmasks, such as SiC or SiO₂, over the Low-k material.

The ability to polish Low-k dielectric materials with the various hardmask integration schemes will be a challenge for the CMP industry. Proposed integration schemes for Low-k dielectrics will require the CMP slurry to planarize as follows: 1) planarize the Low-k ILD or IMD layer; 2) remove the single or dual-top hardmask layer(s); 3) “stop” on the hardmask layer(s); and 4) remove a hardmask layer without removing excess dielectric. Typical chip integration schemes rely upon selective CMP to preferentially remove a metal from a wafer. For example, Brancaleoni et al., in U.S. Pat. No. 5,391,258, disclose the use of various silica suppressants to selectively remove tungsten in the presence of a silica dielectric. In the method of Brancaleoni et al., anions bond with silica substrates to protect the silica substrates' surface from the CMP process. This technique protects the silica substrates' surface during the CMP process without adversely interfering with metal removal. Chip integration schemes for copper and tungsten CMP have adopted this approach to control dielectric removal.

Many chip integration schemes may preferentially remove a silica hardmask (or other hardmasks) and stop on the Low-k barrier material in order to reduce device capacitance and the effective dielectric constant. For example, Kodama et al., in U.S. Pat. No. 5,733,819, disclose the use of alumina, ceria, zirconia and other abrasive particles to preferentially remove a silica film in relation to a Si₃N₄ film. In Kodama et al., a combination of particle composition and slurry chemistry determine a slurry's propensity, if any, to selectively remove silica in relation to the Si₃N₄ film. Typically, maximizing the removal rate selectivity ratio of silica to capping material improves the performance of the polishing slurry.

Most commercial CMP slurries include either colloidal alumina, ceria or silica abrasives for improving planarization and polishing rates. For these colloidal particles to maintain stability, their surface potential or hydration force must overcome the van der Waals forces of the particles. Hosali et al., in U.S. Pub. No. 2001/0013507, disclose abrasive particles having a maximum zeta potential of greater than ±10 milivolts for maintaining a colloidal dispersion stable in an aqueous solution. Since the zeta potential necessary for maintaining colloidal stability varies with operating pH, the preferred operating pH is above or below that pH necessary to achieve the maximum zeta potential.

Unlike the slurries that selectively remove the barrier metal, some Cu/Low-k USLI chip integration schemes will require selective removal of the hardmask material in order to further reduce device capacitance and the effective dielectric constant. For these integration schemes, there exists a need for a slurry that selectively removes the hardmask material, such as SiC, while protecting the relatively soft Low-k dielectric material, such as, organosilicate films (Si_{w}CₓO_{y}H_{z}) from excessive CMP removal. In addition to this, some integration schemes will require the slurry to selectively remove and planarize some of the Low-k material and stop on the Plasma-Enhanced Chemical Vapor Deposition (PECVD) SiO₂ or TEOS material.

### SUMMARY OF THE INVENTION

It has been discovered that zirconia-containing polishing slurries can unexpectedly remove hard silicon carbide hardmask materials at relatively high rates in comparison to more delicate Low-k dielectrics at an acidic pH. In addition, these slurries can provide the additional advantage of stopping on a PECVD SiO₂ hardmask layer, such as a protective TEOS film.

The invention provides a method for removing a hardmask from a semiconductor wafer. This method includes the steps of first introducing a polishing slurry into a wafer-polishing device to cover a wafer with the polishing slurry. The wafer contains a silicon carbide hardmask and a Low-k dielectric. The polishing slurry has a pH of less than 6 and an aqueous dispersion of zirconia particles having a positive zeta potential. The polishing device has a polishing pad. Then planarizing the wafer with motion between the wafer and the polishing pad removes the silicon carbide and the Low-k dielectric. The planarization process removes the silicon carbide at a rate of at least one half the rate of the Low-k dielectric as measured in Å/min.

### BRIEF DESCRIPTION OF THE DRAWING

FIG. 1 is a plot of Low-k removal rate versus pH for slurries containing 1 and 2 weight percent zirconia.

### DETAILED DESCRIPTION OF THE INVENTION

Slurries have been developed that give high removal rates for both Low-k films and silicon carbide hardmask layers for Cu/Low-k integration schemes. Specifically, the slurries contain zirconia within an acidic pH range to remove SiC capping layers and both CVD and SOD Low-k films at comparable rates. These slurries remove all or a portion of a hard silicon carbide hardmask material at a rate of at least one half the rate of Low-k as measured in change in thickness per unit of time or Å/min. The colloidal zirconia-containing slurries can yield up to about 2000 Å/min. for organosilicate Low-k dielectric films such as, (Si_{w}CₓO_{y}H_{z}) and up to about 800 Å/min. for SiC hardmask capping layers. Specific Low-k organosilicates that the slurry planarizes at effective rates include CDO and SiCOH dielectric materials.

In addition to this, the slurry is effective at stopping on PECVD SiO₂ or TEOS material. This will be important when the chip integration scheme incorporates a top hardmask of silicon carbide and a bottom hardmask layer of PECVD SiO₂ over at least a portion of the Low-k film. The CMP method can effectively remove the first hardmask of silicon carbide and stop on the bottom PECVD SiO₂ hardmask layer by removing the silicon carbide hardmask at a rate (Å/min.) of at least twice the removal rate (Å/min.) for the PECVD SiO₂ hardmask. During this method the slurry removes a first portion of the Low-k film layers (typically, not containing a protective hardmask layer) and uses the bottom hardmask as a cap layer to protect a second selected portion of the Low-k dielectric located below the bottom hardmask from polishing.

In addition to stopping on a SiO₂ hardmask layer, the slurry is also effective for removing metallic conductors such as, copper, silver or alloys thereof. The slurry has proven particularly effective for planarizing copper interconnects—the planarizing removes copper interconnect at rate at least ten times greater than the bottom hardmask of PECVD SiO₂ as measured in Å/min.

The polishing method provides an effective method for removing the hardmask for a Low-k dielectric from a semiconductor wafer with a wafer-polishing device for planarizing substrates. The polishing device may include any CMP device for planarizing a surface, such as, a rotary pad-type device or a belt-type design that relies upon a polishing pad having a web configuration. The rotary motion between the polishing pad and the wafer serves to control application of the slurry to remove “high regions” and planarize the wafer's surface.

The use of colloidal zirconia abrasives during polishing, with or without additional liquid chemicals or abrasives, leads to elevated removal rates of both Low-k dielectric and silicon carbide hardmask capping layer materials. For example, the slurry may contain oxidizers, surfactants, biocides, inhibitors and non-zirconia-containing abrasives, such as alumina, ceria and silica. Acceptable oxidizers include hydrogen peroxide, peracetic acid, persulfate, permanganate, ozone, per-acids, per-oxygens, per-phosphates, per-benzoic acid and chlorine dioxide. Furthermore, the zirconia may optionally contain phase stabilizers such as, yttria, ceria and magnesia. Most advantageously, the slurry does not include additional non-zirconia-containing abrasive particles.

Most advantageously, mixing zirconia particles with deionized water forms the aqueous colloidal slurry. Since colloidal zirconia solutions tend to form relatively low pH solutions, it is often advantageous to add a base to the slurry for a pH adjustment. Acceptable bases include ammonium hydroxide, potassium hydroxide and other bases that do not interfere with the slurry's performance.

The relative effectiveness of the colloidal zirconia abrasive contributes to the elevated removal rates of the Low-k dielectric and silicon carbide hardmask capping layer films. The slurry may contain from 0.01 to 20 weight percent colloidal zirconia. This specification lists all concentrations by weight percent in the as diluted for use condition—concentrating the solutions for shipping may produce slurries having a higher percentage of zirconia abrasive. Advantageously, the slurry contains from 0.1 to 10 weight percent colloidal zirconia; and most advantageously, the slurry contains from 0.5 to 5 weight percent colloidal zirconia. In addition, the zirconia advantageously has an average particle size between 2 and 250 nm. Most advantageously, the colloidal zirconia has an average particle size between 5 and 200 nm.

The acidic pH is critical for removing the Low-k dielectric. The pH is typically a value below 6. Advantageously, the pH is between 1.5 and 5.5 to facilitate Low-k removal. Most advantageously, the pH is between 3.5 and 5 for the most efficient Low-k removal. This acidic pH also serves to maintain a positive zeta potential for the abrasive. This positive potential facilitates colloidal stability and provides for effective removal of Low-k and silicon carbide layers. In addition, the positive zeta potential serves to suppress the removal of PECVD SiO₂ hardmask layer, such as TEOS. This is particularly useful for chip integration schemes that incorporate a second hardmask material of PECVD SiO₂ below a silicon carbide cap.

### EXAMPLE

A first series of test slurries contained varied zirconia concentration and pH. The test samples used a 20 wt. percent solution of ZrO₂ as an abrasive source. The specific source of ZrO₂ was a Zr100/20, a bimodal blend of 100 and 20 nm sized particles supplied by Nano Technologies, Inc. Diluting the blend with deionized water and adjusting the pH with ammonium hydroxide produced the test slurries. The following illustrates the slurries' performance for polishing CDO-Low-k using a Strasbaugh 6DS-SP, IC1000-K-XY (on a Suba IV subpad) micro-porous polyurethane polishing pads from Rodel, Inc. with the settings of back-pressure=0, slurry flow rate=200 mL/min for a 30 second polish.

TABLE I

| | | | | | | | | CDO- |
|---|---|---|---|---|---|---|---|---|
| | | | | | | | | Low-k |
| | ZrO₂ | | DF | DF | PS | CS | | RR |
| Slurry | (Wt. %) | pH | (psi) | (kPa) | (rpm) | (rcm) | % NU | (Å/min.) |
| 1 | 2.0 | 4.0 | 3 | 2.1 | 50 | 50 | 18.8 | 6028 |
| 2 | 1.0 | 4.0 | 3 | 2.1 | 50 | 50 | 19.8 | 5132 |
| 3 | 1.0 | 3.5 | 3 | 2.1 | 50 | 50 | 51.6 | 484 |
| 4 | 1.0 | 3.5 | 2 | 1.4 | 50 | 50 | 58.9 | 374 |
| 5 | 1.0 | 3.0 | 3 | 2.1 | 50 | 50 | 62.9 | 263 |
| 6 | 1.0 | 3.0 | 3 | 2.1 | 100 | 100 | 47.8 | 279 |
| 7 | 2.0 | 3.0 | 3 | 2.1 | 50 | 50 | 55.7 | 436 |
| 8 | 2.0 | 4.0 | 3 | 2.1 | 50 | 50 | 30.0 | 6044 |

DF = Carrier Down Force
PS = Platen Speed
CS = Carrier Speed
RR = Removal Rate

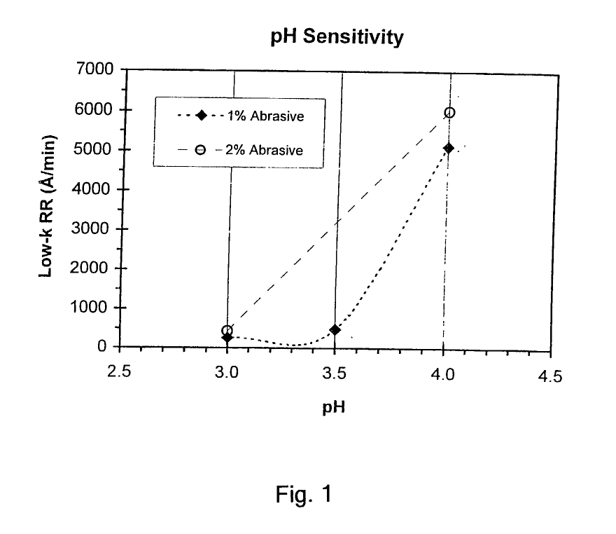

FIG. 1 plots data from Table 1 to show the ability of the colloidal zirconia abrasive to tune or modulate the removal rates of various Low-k dielectrics. These data illustrate that a pH between 3.5 and 5 is particularly effective for removing Low-k dielectrics.

Tables 2 and 3 below summarize the experimental details and polishing results for the Low-k dielectric and silicon carbide hardmask-capping layer materials using planarizing slurry 1 described above. Polishing was performed on the Applied Materials MIRRA polisher on an IC1010 pad at the polishing conditions listed in Tables 2 & 3. Slurry flow rate was 200 mL/min, back pressure was 0 and polish time was 60 s.

TABLE 2

| | | | | | | | SiCOH | |
|---|---|---|---|---|---|---|---|---|
| DF | DF | Platen/Carrier | Cu RR | TaN RR | Ta RR | SiC RR | RR | TEOS RR |
| (psi) | (kPa) | Speeds (rpm) | (Å/min) | (Å/min) | (Å/min) | (Å/min) | (Å/min) | (Å/min) |
| 2 | 1.4 | 60/54 | 1601 | 0 | 0 | 500 | 809 | 72 |
| 2 | 1.4 | 100/94 | 1515 | 0 | 0 | 669 | 802 | 78 |
| 3 | 2.1 | 60/54 | 1411 | 58 | 0 | 626 | 898 | 97 |
| 3 | 2.1 | 100/94 | 1420 | 68 | 0 | 805 | 1005 | 115 |

DF = Downward Force
RR = Removal Rate

TABLE 3

| | | | | | | | CDO | |
|---|---|---|---|---|---|---|---|---|
| DF | DF | Platen/Carrier | Cu RR | TaN RR | Ta RR | Ti RR | RR | TEOS RR |
| (psi) | (kPa) | Speeds (rpm) | (Å/min) | (Å/min) | (Å/min) | (Å/min) | (Å/min) | (Å/min) |
| 2 | 1.4 | 25/19 | 1201 | 27 | 0 | 0 | 1874 | 21 |

DF = Carrier Down Force
RR = Removal Rate

Table 2 shows two main results from colloidal zirconia ILD planarizing slurry 1. First, as shown in column 7, is the ability to remove SiC material. In the test polishing, only a small process window was investigated and the design space explored included down forces of 2 and 3 psi (1.4 and 2.1 kPa) and platen speeds of 60 and 100 rpm. However, it is clear that the SiC hardmask removal rates can modulate from about 500-800 Å/min.

The second novel application of colloidal zirconia slurries is presented in column 8 of Table 2 and shows that slurry 1 can also remove the SiCOH Low-k ILD material. The SiCOH is a PECVD SiO₂ Low-k material doped with carbon that has a k value around 2.7. Table 2 shows SiCOH Low-k removal ranging from about 800-1000 Å/min.

Table 3 reiterates the second point made above and specifically highlights the ability of colloidal zirconia to remove Low-k materials. Column 8 of Table 3 gives the average removal rate for Low-k PECVD carbon-doped-oxide (CDO) materials with k values ranging from about 2.5-3.2. In the experiment summarized in Table 3, the CMP process was optimized for a down force and platen speed of 2 psi (1.4 kPa) and 25 rpm, respectively. This illustrates that even at low down force pressures and slow platen speeds, the removal of the Low-k material is very high at about 1874 Å/min, using colloidal zirconia as the abrasive slurry component.

Slurry 1, representative of the above slurries had a zeta potential of 13 milivolts. This positive potential serves to stabilize the zirconia in the colloidal suspension and facilitate the selective removal of Low-k and SiC in the presence of a TEOS hardmask.

The above data indicate that colloidal zirconia-containing slurries provide effective removal of both silicon carbide and Low-k dielectrics. In addition, these slurries can polish through a silicon carbide hardmask layer to stop on a PECVD SiO₂ hardmask layer, such as TEOS.

We claim:

1. A method of removing a hardmask from a semiconductor wafer comprising the steps of:
introducing a polishing slurry into a wafer-polishing device to cover a wafer with the polishing slurry, the wafer containing a silicon carbide hardmask layer and a Low-k dielectric, the polishing slurry having a pH of less than 6 and containing an aqueous dispersion of zirconia particles having a positive zeta potential, and the polishing device having a polishing pad; and
planarizing the wafer with motion between the wafer and the polishing pad to remove the silicon carbide and the Low-k dielectric with the silicon carbide removal being at a rate of at least one half the rate of the Low-k dielectric as measured in Å/min.

2. The method of claim 1 wherein the step of planarizing the wafer also removes a metallic conductor from the wafer.

3. The method of claim 1 wherein the planarizing removes an organosilicate of the formula (Si_{w}CₓO_{y}H_{z}) as the Low-k dielectric.

4. The method of claim 1 wherein the planarizing stops on a PECVD SiO₂ hardmask layer.

5. The method of claim 1 wherein the planarizing occurs at a pH between 3.5 and 5.

6. A method of removing a hardmask from a semiconductor wafer comprising the steps of:
introducing a polishing slurry into a wafer-polishing device to cover a wafer with the polishing slurry, the wafer containing a top hardmask layer of silicon carbide, a bottom hardmask layer of PECVD SiO₂ and an organosilicate Low-k dielectric of the formula (Si_{w}CₓO_{y}H_{z}), the polishing slurry having a pH of less than 6 and containing an aqueous dispersion of zirconia particles having a positive zeta potential, and the polishing device having a polishing pad; and
planarizing the wafer with motion between the wafer and the polishing pad to remove the top hardmask layer of silicon carbide and a first portion of the organosilicate Low-k dielectric with the top hardmask layer of silicon carbide removal being at a rate of at least one half the rate of the organosilicate Low-k dielectric and at least twice the rate of the second hardmask layer of PECVD SiO₂ as measured in Å/min. to stop on the bottom hardmask layer of PECVD SiO₂ and protect a second portion of the organosilicate Low-k dielectric, the second portion of the organosilicate Low-k dielectric being below the bottom hardmask layer of PECVD SiO₂.

7. The method of claim 6 wherein the step of planarizing the wafer also removes a metallic conductor from the wafer.

8. The method of claim 6 wherein the planarizing removes copper interconnect at rate at least ten times greater than the bottom hardmask of PECVD SiO₂ as measured in Å/min.

9. The method of claim 6 wherein the planarizing removes the organosilicate Low-k dielectric selected from the group consisting of CDO and SiCOH.

10. The method of claim 6 wherein the planarizing occurs at a pH between 3.5 and 5.
